(19) United States
(12) Patent Application Publication
(10) Pub. No.: US 2026/0293012 A1
(43) Pub. Date: Sep. 24, 2026

(54) ELECTRONIC DEVICE HOUSING AND CHARGING DEVICE

(71) Applicant: Anker Innovations Technology Co, Ltd., Changsha (CN)

(72) Inventors: Jianjun Huang, Shenzhen (CN); Songya Chen, Shenzhen (CN); Hongzhi Yan, Shenzhen (CN); Qianer Xu, Shenzhen (CN)

(21) Appl. No.: 19/576,176

(22) Filed: Mar. 24, 2026

(30) Foreign Application Priority Data
Mar. 24, 2025 (CN) 202520526765.2

(51) Int. Cl. H05K 5/02; H05K 5/00

(52) U.S. Cl. CPC H05K 5/0247; H05K 5/0086; H05K 5/0204; H05K 5/0217

(57) ABSTRACT

Disclosed are a housing of an electronic device and a charging device having such a housing. The housing of an electronic device includes a housing body, a bracket, and a cable. The bracket is disposed at the housing body and provided with a first limiting structure and a second limiting structure. One end of the cable is provided with a connector rotatably connected to the bracket and provided with a third limiting structure and a fourth limiting structure. The third limiting structure fits with the first limiting structure to limit a range of rotation angles of the connector relative to the bracket. The fourth limiting structure fits with the second limiting structure to limit movement of the connector in an axial direction. Advantages such as increased stability of the connector during rotation and improved user experience may be achieved.

### CROSS-REFERENCE TO RELATED APPLICATION

This application claims priority to Chinese Patent Application No. 202520526765.2, filed on Mar. 24, 2025, the entire contents of which are incorporated herein by reference.

### FIELD

The present disclosure relates to the technical field of electronic devices, particularly to a housing of an electronic device such as a charging device.

### BACKGROUND

Currently, products with built-in charging cables in the form of a handle cable, such as batteries (power supply), chargers, and wireless network devices, have cables that extend from a side of the product at a substantially fixed angle and cannot freely change a direction thereof according to a user's will, resulting in upwarp of the cable. This not only affects aesthetic appearance of the product but also makes it inconvenient for the user to lift the product, leading to a poor user experience.

Specifically, the direction of the charging cable is unchangeable and has a limited angle of extension from its side, hindering the user from operating and carrying such a product and performing the related actions smoothly. At the same time, the upwarped cable damages the overall visual appeal of the product, reducing attractiveness and feel of quality of the product. This design flaw severely affects the user's satisfaction with the product and willingness to use the product.

### SUMMARY

The present disclosure provides a housing of an electronic device such as a charging device to solve the above technical problem. The present disclosure also provides a charging device with the housing.

In a first aspect, the present disclosure provides a housing of an electronic device, comprising: a housing body; a bracket disposed at the housing body and provided with (e.g., comprising) a first limiting structure and a second limiting structure; and a cable comprising a connector (e.g., at one end thereof), the connector being configured to rotatably connect to the bracket and provided with (e.g., comprising) a third limiting structure and a fourth limiting structure. The third limiting structure is configured to fit with the first limiting structure to limit a range of rotation angles of the connector relative to the bracket. The fourth limiting structure is configured to fit with the second limiting structure to limit movement of the connector in an axial direction.

Further, the bracket may comprise a mounting hole, and the connector may be configured to pass through the mounting hole. The second limiting structure may comprise an annular limiting protrusion, and the annular limiting protrusion may protrude on/from a wall of the mounting hole.

The fourth limiting structure may comprise a first limiting recess. The first limiting recess may be recessed on a periphery of the connector. The annular limiting protrusion may be configured to be movably received (e.g., restricted, limited) within the first limiting recess, to limit movement of the connector in an axial direction.

Alternatively, the second limiting structure may comprise a first limiting recess, and the fourth limiting structure may comprise an annular limiting protrusion. The annular limiting protrusion may be configured to be movably received within the first limiting recess, to limit movement of the connector in an axial direction.

Further, the first limiting structure may comprise a limiting block, and the limiting block may protrude on/from a wall of the mounting hole.

The third limiting structure may comprise a second limiting recess. The second limiting recess may be recessed on the periphery of the connector and may be spaced apart from the first limiting recess. The limiting block may be configured to be movably received (e.g., restricted) within the second limiting recess, so as to limit the range of rotation angles of the connector relative to the bracket based on a central angle of an arc formed by the second limiting recess extending along a circumferential direction of the connector.

Alternatively, the third limiting structure may comprise a limiting block, and the first limiting structure may comprise a second limiting recess. The limiting block may be configured to be movably received within the second limiting recess, so as to limit the range of rotation angles of the connector relative to the bracket based on a central angle of an arc formed by the second limiting recess extending along a circumferential direction of the connector.

Further, the central angle of the arc formed by the second limiting recess extending along the circumferential direction of the connector may be 180°.

Further, the bracket may comprise a first bracket body provided with (e.g., comprising) a first semi-recess and a second bracket body provided with (e.g., comprising) a second semi-recess. The first bracket body and the second bracket body may be aligned, so that the first semi-recess and the second semi-recess may enclose to define a mounting hole configured for the connector to pass through.

The first semi-recess may be provided with (e.g., comprise) a first arc protrusion. The second semi-recess may be provided with (e.g., comprise) a second arc protrusion and the limiting block that are spaced apart. Two ends of the first arc protrusion may abut against two ends of the second arc protrusion respectively to form an annular limiting protrusion.

Further, the housing may comprise one or more fasteners. The first bracket body may be provided with (e.g., comprise) first lugs at both ends, each first lug provided with (e.g., having) a first connecting hole. The second bracket may be provided with (e.g., comprise) second lugs at both ends, each second lug provided with (e.g., having) a second connecting hole. The first lugs may be configured to align with the second lugs, and the bracket and the housing body may be configured to be connected by one or more fasteners passing through the first connecting hole and the second connecting hole.

Further, the housing body may comprise an accommodating cavity and a cable-passing hole communicating with the accommodating cavity. The bracket may be configured to be located in the accommodating cavity, and the connector may be configured to pass through the cable-passing hole.

Further, the housing may comprise a bearing. A cavity wall of the accommodating cavity may be provided with (e.g., comprise) an assembly recess corresponding to the cable-passing hole. The bearing may be sleeved on the connector 4 and may be received (e.g., restricted) within the assembly recess.

Further, the assembly recess may be a non-circular recess. An outer ring of the bearing may be non-circular. The assembly recess may accommodate the outer ring of the bearing. The outer ring of the bearing and the assembly recess may be in limiting fitting.

An inner ring of the bearing may be non-circular. The periphery of the connector may be provided with (e.g., comprise) an irregular ring. The inner ring may accommodate the irregular ring. The irregular ring of the connector and the inner ring of the bearing may be in limiting fitting.

Further, the bracket may comprise an abutting protrusion on a side thereof facing an inner ring of the bearing.

Further, the cable may be configured to extend along a side of the housing body. The cable may be configured to extend away from a side of the housing body.

In a second aspect, the present disclosure provides a charging device comprising: a charging device body; and the housing of an electronic device as described above. The charging device body may be disposed inside the housing body, and the cable may be electrically connected to the charging device body.

The technical solutions provided by examples of the present disclosure may have advantages such as the following:

In the technical solutions provided by examples of the present disclosure, the connector and the bracket may be rotatably connected, enabling the relative rotation between the cable and the housing body. The rotation of the cable may facilitate carrying, storage, and the like, for example, during use of the charging device, and ensure the user experience. Meanwhile, in the present disclosure, the bracket may limit movement of the connector in the axial direction by the fitting between the second limiting structure and the fourth limiting structure. Accordingly, stability of the connector during rotation may be ensured, and the connector may be prevented from moving in the axial direction relative to the bracket. Furthermore, the angle of rotation of the connector relative to the bracket may be limited by the fitting between the first limiting structure and the third limiting structure. Accordingly, there are at least two stable fitting states between the bracket and the connector, thereby improving the user experience.

### BRIEF DESCRIPTION OF THE DRAWINGS

Accompanying drawings, which are incorporated in and constitute a part of this specification, illustrate examples according to the disclosure, which together with the specification serve to explain principles of the disclosure.

In order to more clearly illustrate technical solutions in examples of the present disclosure or the related art, drawings that need to be used in description of the examples are briefly introduced below, and it will be apparent to those of ordinary skill in the art that the drawings in the following description are only some examples of the disclosure, and other drawings can be obtained in accordance with these drawings without inventive work.

One or more examples are illustrated by figures in the corresponding drawings, which does not constitute a limitation of the examples. Elements with the same reference numerals in the drawings represent similar elements, and the drawings do not constitute scale limitation unless otherwise specified.

FIG. 1 is a structural diagram of a housing of an electronic device in a first state according to an example of the present disclosure;

FIG. 2a is a cross-sectional view of FIG. 1;

FIG. 2b is a cross-sectional view from another angle of assembly of a connector and a bracket in FIG. 1;

FIG. 3 is an exploded diagram of FIG. 1;

FIG. 4 is a diagram of part of the structures in FIG. 3;

FIG. 5 is a structural diagram of a bracket in FIG. 4;

FIG. 6 is a diagram of a fitting position of a second limiting surface of a connector and a limiting block when a housing of an electronic device is in a first state according to an example of the present disclosure;

FIG. 7 is an enlarged view of part B in FIG. 6;

FIG. 8 is a structural diagram of a housing of an electronic device in a second state according to an example of the present disclosure;

FIG. 9 is a diagram of a fitting position of a first limiting surface of a connector and a limiting block when a housing of an electronic device is in a second state according to an example of the present disclosure; and

FIG. 10 is an enlarged view of part A in FIG. 9.

Description of reference signs: 1: housing body; 1a: accommodating cavity; 1 b: cable-passing hole; 1c: assembly recess; 2: bracket; 21: first limiting structure; 22: second limiting structure; 2a: mounting hole; 23: annular limiting protrusion; 24: limiting block; 25: first bracket body; 25 a: first semi-recess; 231: first arc protrusion; 251: first lug; 26: second bracket body; 26a: second semi-recess; 232: second arc protrusion; 261: second lug; 27: abutting protrusion; 3: cable; 4: connector; 41: third limiting structure; 42: fourth limiting structure; 4a: first limiting recess; 4b: second limiting recess; 4c: limiting surface; 4d: first limiting surface; 4e: second limiting surface; 43: baffle; 44: irregular ring; 5: bearing.

### DETAILED DESCRIPTION

In order to make objects, technical solutions, and advantages of examples of the disclosure clearer, the technical solutions in the examples of the disclosure will be clearly and fully described in combination with the accompanying drawings in the examples of the present disclosure. Obviously, the examples to be described are part of examples but not all examples of the disclosure. Based on the examples of the disclosure, all other examples obtained by those of ordinary skill in the art without inventive work shall fall within the scope of the disclosure.

Many different examples are disclosed below to realize different structures of the disclosure. In order to simplify the disclosure, components and arrangements of specific examples are described below. Of course, they are only exemplary and are not intended to limit the disclosure. Furthermore, the present disclosure may repeat reference numerals and/or letters in different examples. The repetition is for simplicity and clarity, and in itself does not indicate the relationship between the various examples and/or arrangements discussed.

For the convenience of description, spatial relative relationship terms can be used herein to describe the relative positional relationship or movement status of one element or feature relative to another element or feature as shown in the drawings, such as “inside”, “outside”, “inner”, “outer”, “under”, “below”, “on”, “above”, “front” and “back”. Such spatial relative relationship terms are intended to include different orientations of the device in use or operation other than orientations depicted in the drawings. For example, if the device in the drawings has a position turnover, a posture change or a movement status change, these directional indications will change accordingly, for example: elements described as “under or below other elements or features” will be subsequently oriented as “on or over other elements or features”. Thus, the exemplary term “below” may include both orientations of above and below. The device may be otherwise oriented (rotated by 90 degrees or in other directions), and the spatial relative relationship description used herein are interpreted accordingly.

To solve the technical problem of poor user experience caused by a fixed structure of a data cable or charging cable in a charging device in the related art, the present disclosure provides a housing for an electronic device such as a charging device, which may improve the user experience. The present disclosure also provides a charging device with such a housing.

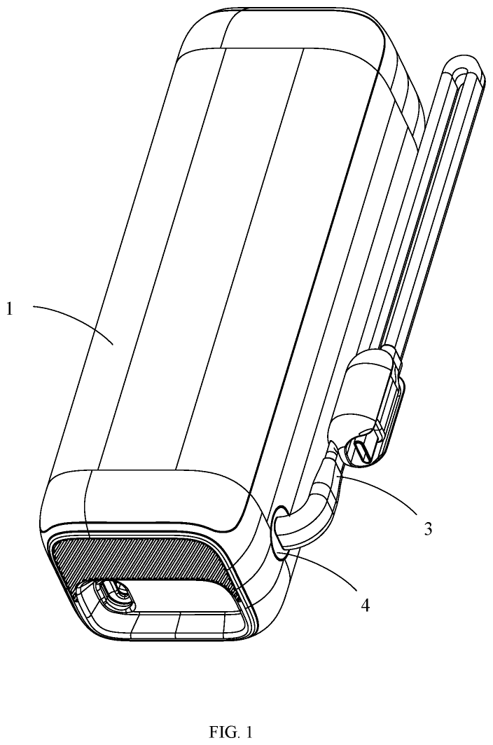

In a first aspect, as illustrated in FIGS. 1 to 10, the present disclosure provides a housing of an electronic device, which may be applied to various electronic devices, such as power banks, chargers, and wireless network devices. The housing of an electronic device may comprise a housing body 1, a bracket 2, and a cable 3. An electronic device may comprise a cable (e.g., a charging cable and/or a data cable). For example, the cable (e.g., cable 3) may lead out from a circuit board, and can be used to connect to other external devices (such as mobile phones, smart bands, and/or computers).

The bracket 2 may be disposed at (e.g., mounted on, attached to, integrally formed with, coupled to, disposed on, extending from, formed on, positioned adjacent to, inside, etc.) the housing body 1. The bracket 2 may be provided with (e.g., comprise) a first limiting structure 21 and a second limiting structure 22. A limiting structure may be, for example, a stop structure/member/surface, a protrusion, a ridge, a flange, a blocking element, or any other structure configured to limit movement of corresponding component. One end of the cable 3 may be provided with (e.g., comprise) a connector 4. The connector 4 may be rotatably connected to the bracket 2. The connector 4 may be provided with (e.g., comprise) a third limiting structure 41 and a fourth limiting structure 42. The third limiting structure 41 may fit with the first limiting structure 21, for example, to limit a range of rotation angles (or a rotation angle range) of the connector 4 relative to the bracket 2. The fourth limiting structure 42 may fit with the second limiting structure 22, for example, to limit movement of the connector 4 in an axial direction.

As described herein, the connector 4 and the bracket 2 may be rotatably connected, allowing the relative rotation between the cable 3 and the housing body 1. The capability of rotation of the cable 3 may facilitate carrying, storage, and various activities during use, which may improve the user experience. The bracket 2 may limit the movement of the connector 4 in the axial direction by the fitting between the second limiting structure 22 and the fourth limiting structure 42. For example, the connector 4 may be prevented from moving in the axial direction relative to the bracket 2. Stability of the connector 4 during rotation (e.g., stable rotation) may be realized. Furthermore, the angle of rotation of the connector 4 relative to the bracket 2 may be limited by the fitting between the first limiting structure 21 and the third limiting structure 41. Accordingly, there are at least two stable fitting states between the bracket 2 and the connector 4, thereby improving the user experience.

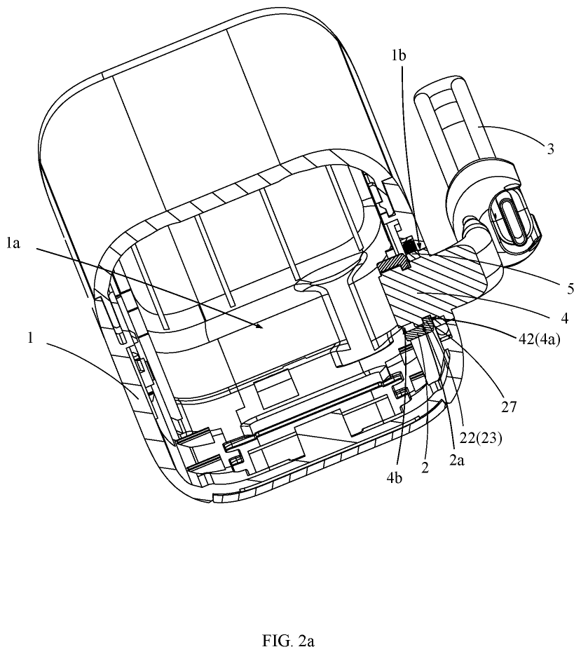

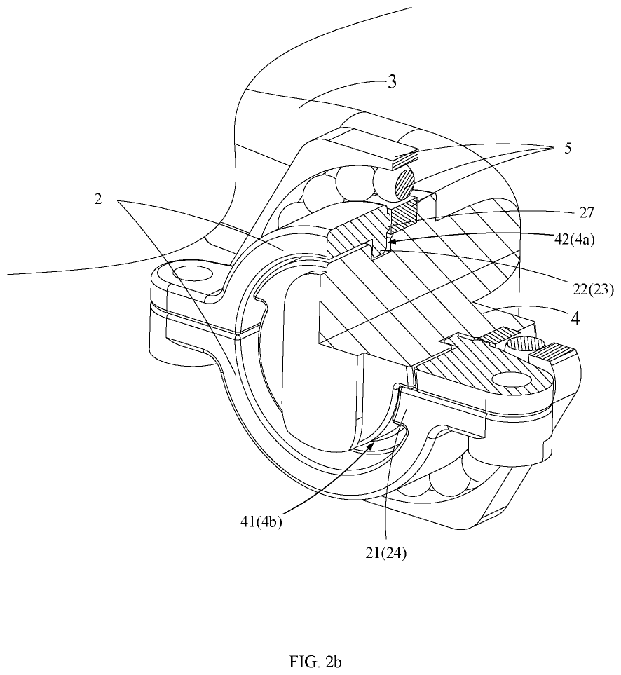

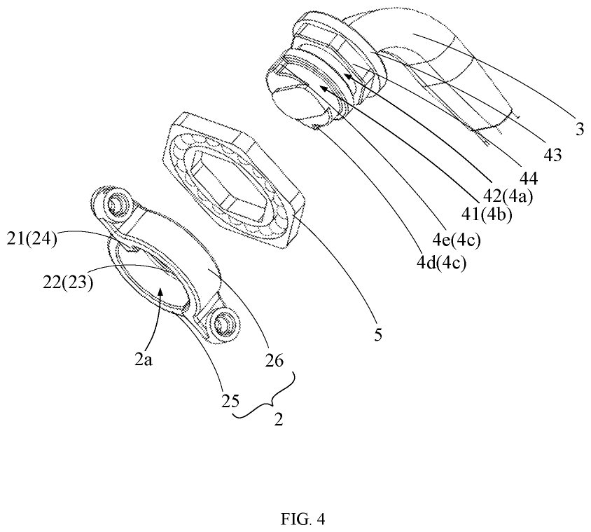

As illustrated in FIG. 2a, FIG. 2b and/or FIG. 4, in an example of the present disclosure, the bracket 2 may comprise a mounting hole 2a. A wall of the mounting hole 2a may be provided with (e.g., comprise) an annular limiting protrusion 23. The annular limiting protrusion 23 may be generally ring-shaped. For example, the annular limiting protrusion may or may not be perfectly circular or uniform. For example, the annular limiting protrusion may be an oval ring, a polygonal ring, a ring with small interruptions, or any other structure as long as the structure surrounds the axis in a ring-like manner. The annular limiting protrusion 23 may be continuous or non-continuous. For example, the annular limiting protrusion may comprise spaced protrusions/segments around a circle. For example, the annular limiting protrusion may be a partial ring.

The connector 4 may pass through the mounting hole 2a. A periphery of the connector 4 may be provided with (e.g., comprise) a first limiting recess 4a. The annular limiting protrusion 23 may be movably received (e.g., restricted) within the first limiting recess 4a. The annular limiting protrusion 23 may be an example of the second limiting structure 22. The first limiting recess 4a may be an example of the fourth limiting structure 42. The bracket 2 may limit the movement of the connector 4 in the axial direction by the limiting fitting of the annular limiting protrusion 23 and the first limiting recess 4a, which is simple in structure and easy to process (e.g., manufacture). The fitting between the annular limiting protrusion 23 and the first limiting recess 4a may play a positioning role, during the assembly process of the connector 4 and the bracket 2, which may facilitate quick assembly of the connector 4 and the bracket 2. After the assembly is completed, the bracket 2 limits the movement of the connector 4 in the axial direction, without additional axial limiting components. In an example, the first limiting recess 4a extends along the periphery of the connector 4 to form a circular annular recess, which may ensure that the fitting between the annular limiting protrusion 23 and the first limiting recess 4a does not affect the rotation of the connector 4 relative to the bracket 2.

In some other examples, the periphery of the connector 4 may be provided with (e.g., comprise) the annular limiting protrusion 23, and the wall of the mounting hole 2a of the bracket 2 may be provided with (e.g., comprise) the first limiting recess 4a. The annular limiting protrusion 23 may be movably received (e.g., restricted) within the first limiting recess 4a. The first limiting recess 4a may be an example of the second limiting structure 22. The annular limiting protrusion 23 may be an example of the fourth limiting structure 42.

In an example of the present disclosure (e.g., as illustrated in FIG. 4), the periphery of the connector 4 may be provided with (e.g., comprise) a second limiting recess 4b. The second limiting recess 4b and the first limiting recess 4a may be spaced apart. The second limiting recess 4b may extend along a periphery of the connector 4. The second limiting recess 4b may comprise two ends (e.g., end surfaces) which may form limiting surfaces 4c on the connector 4.

A limiting block 24 may be provided in the mounting hole 2a (e.g., on the wall of the mounting hole 2a). The limiting block 24 may be movably received (e.g., restricted) within the second limiting recess 4b. The limiting block 24 may be an example of the first limiting structure 21. The second limiting recess 4b may be an example of the third limiting structure 41.

The range of rotation angles of the connector 4 may be limited by the two limiting surfaces 4c formed by the second limiting recess 4b on the connector 4. For example, as illustrated in FIG. 4, the two limiting surfaces 4c are a first limiting surface 4d and a second limiting surface 4e, respectively.

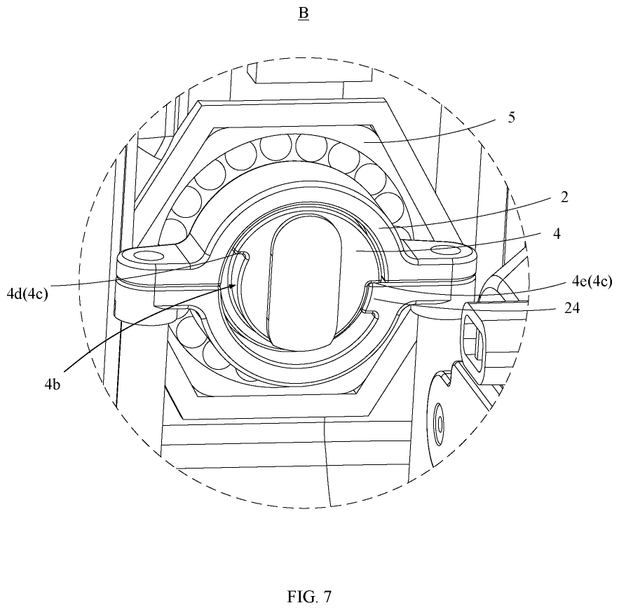

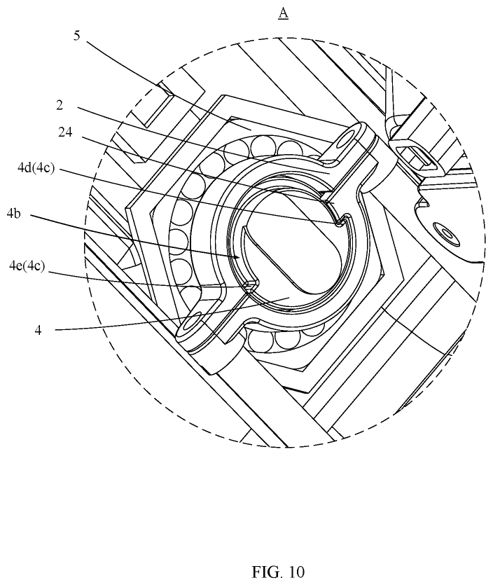

The second limiting surface 4e may abut against one side of the limiting block 24, for example, when the connector 4 is rotated to a first state, as shown in FIG. 7. The first limiting surface 4d may abut against the other side of the limiting block 24, for example, when the connector 4 is rotated to a second state, as shown in FIG. 10. In an example, the limiting block 24 and the bracket 2 are integrally formed, which is simple in structure and easy to process (e.g., manufacture).

In other examples, the connector 4 may be provided with (e.g., comprise) the limiting block 24, and the mounting hole 2a of the bracket 2 may be provided with (e.g., comprise) the second limiting recess 4b. The second limiting recess 4b may be an example of the first limiting structure 21, and the limiting block 24 may be an example of the third limiting structure 41.

In an example of the present disclosure, a central angle of an arc formed by the second limiting recess 4b extending along a circumferential direction of the connector 4 ranges from 90° to 300°. It should be noted that in some other examples, the second limiting recess 4 b may also be an annular recess extending along the circumferential direction of the connector 4. The central angle of the arc formed by the second limiting recess 4b extending along the circumferential direction of the connector 4 may be less than 90° or greater than 300°.

The central angle of the arc formed by the second limiting recess 4b extending along the circumferential direction of the connector 4 may be 180°, for example, as in the example as shown in FIG. 4.

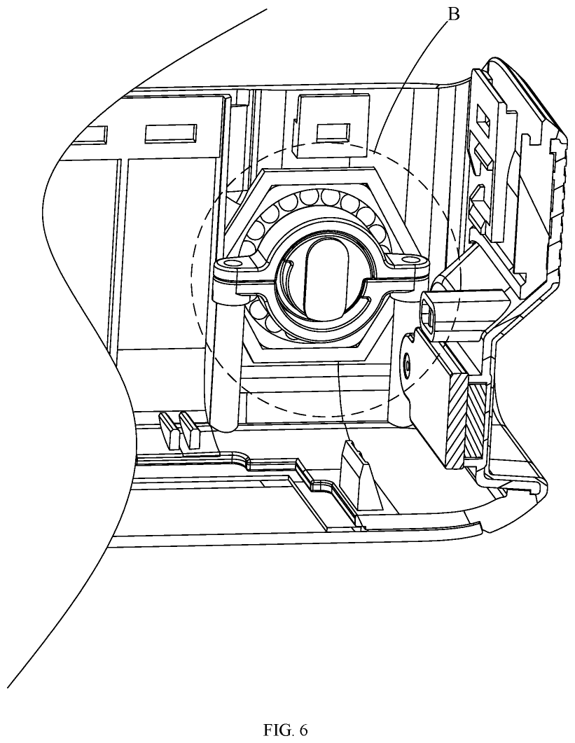

FIG. 1 is a diagram of the cable 3 and the housing body 1 in the first state. FIGS. 6 and 7 are diagrams illustrating relative positions of the connector 4 and the bracket 2 in the first state as viewed from the inside of the housing body 1. Specifically, in the first state, the cable 3 and the housing body 1 are at 0° (e.g., forming an angle of 0°). That is, the cable 3 extends along a side of the housing body 1, and the cable 3 is basically parallel to the side of the housing body 1. The third limiting structure 41 abuts against and fits with the first limiting structure 21, so that the first state is a stable limiting fitting state.

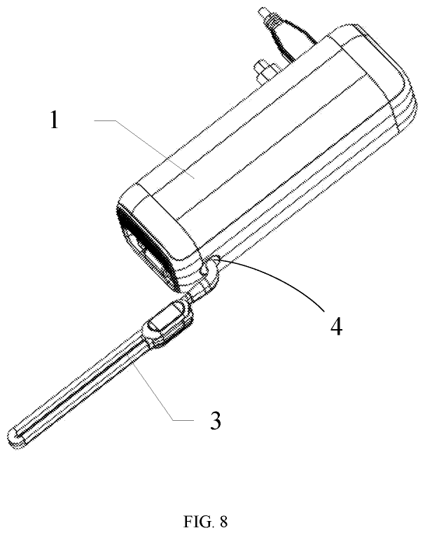

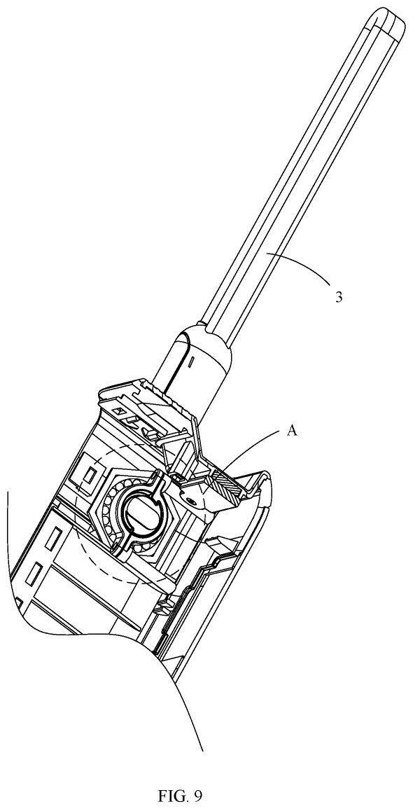

FIG. 8 is a diagram of the cable 3 and the housing body 1 in the second state. FIGS. 9 and 10 are diagrams illustrating relative positions of the connector 4 and the bracket 2 in the second state as viewed from the inside of the housing body 1. Specifically, in the second state, the cable 3 and the housing body 1 are at 180° (e.g., forming an angle of 180°). That is, the cable 3 extends away from a side of the housing body 1, and the cable 3 is basically parallel to the side of the housing body 1. The third limiting structure 41 abuts against and fits with the first limiting structure 21, so that the second state is a stable limiting fitting state.

An angle of relative rotation between cable 3 and housing body 1 ranges from 0° to 180°.

In an example, the annular limiting protrusion 23 and the limiting block 24 may be spaced apart, and a protrusion may be formed between the first limiting recess 4a and the second limiting recess 4b. The protrusion may be sandwiched between the annular limiting protrusion 23 and the limiting block 24, thereby further strengthening axial limiting fitting between the connector 4 and the bracket 2 and improving stability of the connector 4 in the axial direction.

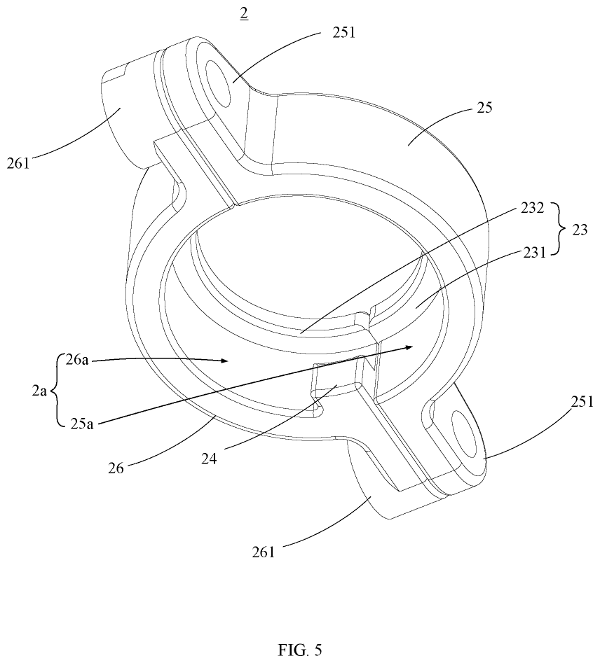

In an example of the present disclosure (e.g., as illustrated in FIG. 5), the bracket 2 may comprise a first bracket body 25 and a second bracket body 26. The first bracket body 25 may be provided with (e.g., comprise) a first semi-recess 25a. The first semi-recess 25a may be provided with (e.g., comprise) a first arc protrusion 231. The second bracket body 26 may be provided with (e.g., comprise) a second semi-recess 26a. The second semi-recess 26a may be provided with (e.g., comprise) a second arc protrusion 232 and the limiting block 24 that are spaced apart. The first bracket body 25 and the second bracket body 26 are connected, so that the first semi-recess 25a and the second semi-recess 26a enclose to define the mounting hole 2a. Two ends of the first arc protrusion 231 may abut against two ends of the second arc protrusion 232 respectively to form the annular limiting protrusion 23. The design of the bracket 2 as a structure formed by fitting between the first bracket body 25 and the second bracket body 26 can facilitate the assembly of the connector 4 and the bracket 2.

In an example of the present disclosure (e.g., as illustrated in FIG. 5), the first bracket body 25 may be provided with (e.g., comprise) first lugs 251 at both ends. Each of the first lugs 251 may be provided with (e.g., comprise) a first connecting hole. The second bracket 26 may be provided with (e.g., comprise) second lugs 261 at both ends. Each of the second lug 261 may be provided with (e.g., comprise) a second connecting hole. The first lugs 251 and the second lugs 261 may be aligned, and the bracket 2 and the housing body 1 may be connected by fasteners passing through the first connecting hole and the second connecting hole. This may facilitate the assembly of the bracket 2 and the housing body 1. The provision of the first lugs 251 and the second lugs 261 not only provides assembly positions for the fasteners, but also improves structural strength of the bracket 2.

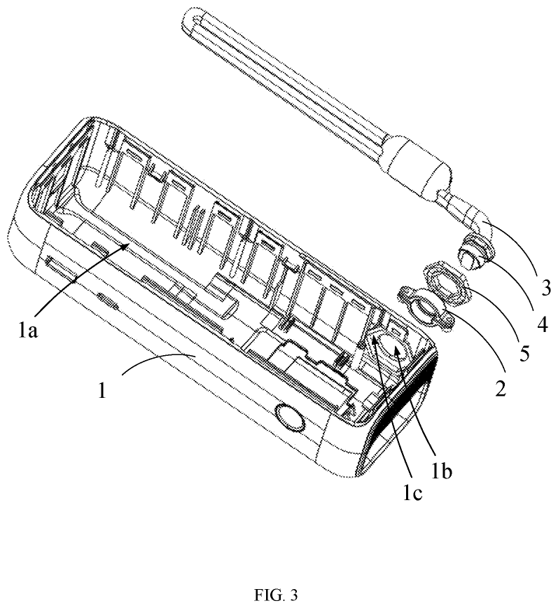

In an example of the present disclosure (e.g., as illustrated in FIGS. 2a and 3), the housing body 1 may have an accommodating cavity 1a and a cable-passing hole 1b communicating with the accommodating cavity 1a. The bracket 2 may be located in the accommodating cavity 1a, and the connector 4 may pass through the cable-passing hole 1b. As described herein, the bracket 2 may be hidden inside the housing body 1. Advantages such as protecting a joint between the bracket 2 and the connector 4, preventing foreign objects from intrusion and affecting the fitting between the bracket 2 and the connector 4, and facilitating electrical connection between the cable 3 and the circuit board inside the housing body 1 may be realized.

In an example, a baffle 43 may be provided at the periphery of the connector 4. A periphery of the baffle 43 may fit with a wall of the cable-passing hole 1b. Sealing performance between the connector 4 and the cable-passing hole 1b may be improved.

In an example of the present disclosure (e.g., as illustrated in FIGS. 2a, 3 and 4), the assembly may comprise a bearing 5. A cavity wall of the accommodating cavity 1a may be provided with (e.g., comprise) an assembly recess 1c corresponding to the cable-passing hole 1b. The bearing 5 may be sleeved on the connector 4 and may be received (e.g., restricted) within the assembly recess 1c. As described herein, the assembly recess 1c may provide an installation position for the bearing 5. By providing the bearing 5, frictional resistance during the rotation of the connector 4 may be significantly reduced, making the rotation of the cable 3 smoother. Reliability and durability of the rotation operation may be greatly improved, realizing consistent performance during long-term use, and reducing the risk of failure and damage that may be caused by poor or unstable rotation.

In an example of the present disclosure (e.g., as illustrated in FIG. 3), the assembly recess 1c may be a non-circular recess, and an outer ring of the bearing 5 may be non-circular. An outer ring of the bearing 5 and the assembly recess 1c may be in limiting fitting (or form a limiting engagement). In this way, after the assembly recess 1c has fitted with the bearing 5, the assembly recess 1c plays a limiting role on the outer ring of the bearing 5, which can prevent the outer ring of the bearing 5 from rotating relative to the housing body 1.

An inner ring of the bearing 5 may be non-circular. The periphery of the connector 4 may be provided with (e.g., comprise) an irregular ring 44. The irregular ring 44 and the inner ring of the bearing 5 may be in limiting fitting. In this way, after the connector 4 has fitted with bearing 5, the irregular ring 44 of the connector 4 plays a limiting role on the inner ring of the bearing 5, preventing the inner ring of the bearing 5 from rotating relative to the connector 4.

In an example of the present disclosure, the bearing 5 is a ball bearing. There are balls between the outer ring and the inner ring of the bearing 5, which can ensure that when the inner ring of the bearing 5 rotates under the drive of the connector 4, the outer ring of the bearing 5 can be stably limited within the assembly recess 1c.

In an example of the present disclosure (e.g., as illustrated in FIG. 2a), the bracket 2 may have an abutting protrusion 27 on a side thereof facing the inner ring of the bearing 5. Accordingly, wear resistance of the bracket 2 can be improved.

On the other hand, the present disclosure provides a charging device comprising a charging device body and the housing of an electronic device as described above. The charging device body is disposed inside the housing body 1, and the cable 3 is electrically connected to the charging device body. The specific structure of the housing of an electronic device refers to the above examples. The charging device adopts all the technical solutions of all the above examples, and thus at least has all the beneficial effects of the technical solutions of the above examples, which will not be repeated here.

In an example, the charging device is a power bank, and the charging device body is a charging and discharging device. The power bank may comprise the housing body 1, a charging and discharging device, a circuit board, and the cable 3. The cable 3 is rotatably connected to the housing body 1 through fitting between the connector 4 and the bracket 2. The charging and discharging device and the circuit board are disposed inside the housing body 1. One end of the cable 3 is electrically connected to the circuit board, and the other end of the cable 3 is configured to connect to an external device. Thus, the charging and discharging device can be electrically connected to the external device through the cable 3 for charging or discharging.

In the above examples, the description of each example has a focus. For parts not detailed in an example, one can refer to the relevant descriptions in other examples.

In description of the disclosure, it should be understood that orientation or position relationships indicated by the terms “center”, “longitudinal”, “transverse”, “length”, “width”, “thickness”, “upper”, “lower”, “front”, “rear”, “left”, “right”, “vertical”, “horizontal”, “top”, “bottom”, “inside”, “outside”, “clockwise”, “counterclockwise”, and the like are based on the orientation or position relationships shown in the drawings, which are only for the convenience of describing the disclosure and simplifying the description, and do not indicate or imply that the referred device or element must have a specific orientation and be constructed and operated in a specific orientation, and thus cannot be understood as a limit of the disclosure.

In addition, the terms “first” and “second” are used for a descriptive purpose only and are not to be construed as indicating or implying the relative importance or implicitly indicating the number of indicated technical features. Thus, features defined with “first” and “second” may explicitly or implicitly include at least one of such features. In the description of the present disclosure, “a plurality of” means at least two, unless otherwise explicitly and specifically defined herein.

In the present disclosure, terms such as “mount”, “communicate”, “connect”, and “fix” should be understood broadly unless expressly specified or defined. For example, the terms may refer to fixed connection, detachable connection, or integration; may refer to mechanical connection or electrical connection; may refer to direct connection, indirect connection via an intermediary, or internal communication or interaction relationship between two elements, unless expressly defined. Specific meanings of the above terms in the present disclosure may be understood by those of ordinary skill in the art in light of specific circumstances.

In the present disclosure, unless otherwise explicitly specified and defined, if a first feature is described as “above” or “below” a second feature, it may mean that the first and second features are in direct contact or in indirect contact through another feature therebetween. Furthermore, the first feature being “above”, “upon” and “on” the second feature includes the first feature being directly above or obliquely above the second feature, or simply mean that the first feature is higher than the second feature in the horizontal height. Furthermore, the first feature being “below”, “beneath” and “under” the second feature includes the first feature being directly below or obliquely below the second feature, or simply mean that the first feature is lower than the second feature in the horizontal height.

In the description of the disclosure, description of the reference terms “an embodiment”, “some embodiments”, “an example”, “a specific example”, “some examples”, and the like means that a specific feature, structure, material, or characteristic described in combination with the embodiment or example is included in at least one embodiment or example of the disclosure. In the description, an illustrative recitation of the above terms does not necessarily refer to the same embodiment or example. Furthermore, the specific feature, structure, material or characteristic described may be combined in any suitable manner in any one or more embodiments or examples. In addition, those skilled in the art can incorporate and combine different embodiments or examples and features of different embodiments or examples described in the description without contradicting each other.

Obviously, those skilled in the art can make various modifications and variations to the present disclosure without departing from the spirit and scope of the present disclosure. Thus, it is intended that the present disclosure covers the modifications and variations provided they fall within the scope of the appended claims and equivalents thereof.

The foregoing descriptions are merely specific implementations of the present disclosure, but are not intended to limit the scope of protection of the present disclosure. Any equivalent modification or replacement readily thought of by those skilled in the art within the technical scope disclosed in the present disclosure shall fall within the scope of protection of the present disclosure. Therefore, the scope of protection of the present disclosure shall be subject to the scope of protection of the claims.

What is claimed is:

1. A housing of an electronic device, comprising:
a housing body;
a bracket disposed at the housing body and comprising a first limiting structure and a second limiting structure; and
a cable comprising a connector, wherein the connector is configured to rotatably connect to the bracket and comprises a third limiting structure and a fourth limiting structure, wherein
the third limiting structure is configured to fit with the first limiting structure to limit a range of rotation angles of the connector relative to the bracket; and
the fourth limiting structure is configured to fit with the second limiting structure to limit movement of the connector in an axial direction.

2. The housing of the electronic device of claim 1, wherein the bracket comprises a mounting hole, and the connector is configured to pass through the mounting hole, and
wherein the second limiting structure comprises an annular limiting protrusion, the annular limiting protrusion protruding from a wall of the mounting hole.

3. The housing of the electronic device of claim 1, wherein the second limiting structure comprises an annular limiting protrusion,
wherein the fourth limiting structure comprises a first limiting recess on a periphery of the connector, and
wherein the annular limiting protrusion is configured to be movably received within the first limiting recess, to limit movement of the connector in an axial direction.

4. The housing of the electronic device of claim 1, wherein the second limiting structure comprises a first limiting recess,
wherein the fourth limiting structure comprises an annular limiting protrusion, and
wherein the annular limiting protrusion is configured to be movably received within the first limiting recess, to limit movement of the connector in an axial direction.

5. The housing of the electronic device of claim 1, wherein the bracket comprises a mounting hole, and the first limiting structure comprises a limiting block protruding from a wall of the mounting hole.

6. The housing of the electronic device of claim 1, wherein the fourth limiting structure comprises a first limiting recess on a periphery of the connector, and
wherein the third limiting structure comprises a second limiting recess on the periphery of the connector, the second limiting recess being spaced apart from the first limiting recess.

7. The housing of the electronic device of claim 1, wherein the third limiting structure comprises a second limiting recess on a periphery of the connector, and the first limiting structure comprises a limiting block, and
wherein the limiting block is configured to be movably received within the second limiting recess, so as to limit the range of rotation angles of the connector relative to the bracket based on a central angle of an arc formed by the second limiting recess extending along a circumferential direction of the connector.

8. The housing of the electronic device of claim 1, wherein the third limiting structure comprises a limiting block, and the first limiting structure comprises a second limiting recess, and
wherein the limiting block is configured to be movably received within the second limiting recess, to limit the range of rotation angles of the connector relative to the bracket based on a central angle of an arc formed by the second limiting recess extending along a circumferential direction of the connector.

9. The housing of the electronic device of claim 1, wherein the third limiting structure comprises a second limiting recess on a periphery of the connector and extending along a circumferential direction of the connector, the second limiting recess forming an arc, and
wherein a central angle of the arc is 180°.

10. The housing of the electronic device of claim 1, wherein the bracket comprises:
a first bracket body comprising a first semi-recess; and
a second bracket body comprising a second semi-recess,
wherein the first bracket body and the second bracket body are aligned, so that the first semi-recess and the second semi-recess enclose to define a mounting hole configured for the connector to pass through.

11. The housing of the electronic device of claim 10, wherein the first semi-recess comprises a first arc protrusion, and the second semi-recess comprises a second arc protrusion, and
wherein two ends of the first arc protrusion abut against two ends of the second arc protrusion respectively to form an annular limiting protrusion.

12. The housing of the electronic device of claim 10, wherein the first bracket body comprises first lugs at both ends, each first lug having a first connecting hole, and the second bracket body comprises second lugs at both ends, each second lug having a second connecting hole, and
wherein the first lugs are configured to align with the second lugs, and the bracket and the housing body are configured to be connected by one or more fasteners passing through the first connecting hole and the second connecting hole.

13. The housing of the electronic device of claim 1, wherein the housing body comprises an accommodating cavity and a cable-passing hole communicating with the accommodating cavity, and wherein the bracket is configured to be located in the accommodating cavity, and the connector is configured to pass through the cable-passing hole.

14. The housing of the electronic device of claim 13, further comprising a bearing, wherein a cavity wall of the accommodating cavity comprises an assembly recess corresponding to the cable-passing hole, and wherein the bearing is received within the assembly recess.

15. The housing of the electronic device of claim 14, wherein the assembly recess is a non-circular recess and forms a limiting engagement with an outer ring of the bearing.

16. The housing of the electronic device of claim 14, wherein an inner ring of the bearing is non-circular and forms a limiting engagement with an irregular ring on a periphery of the connector.

17. The housing of the electronic device of claim 14, wherein the bracket comprises an abutting protrusion on a side thereof facing an inner ring of the bearing.

18. The housing of the electronic device of claim 1, wherein the cable is configured to extend along a side of the housing body.

19. The housing of the electronic device of claim 1, wherein the cable is configured to extend away from a side of the housing body.

20. A charging device comprising:
a charging device body; and
a housing of an electronic device comprising:
a housing body;
a bracket disposed at the housing body and comprising a first limiting structure and a second limiting structure; and
a cable comprising a connector, wherein the connector is configured to rotatably connect to the bracket and comprises a third limiting structure and a fourth limiting structure, wherein
the third limiting structure is configured to fit with the first limiting structure to limit a range of rotation angles of the connector relative to the bracket; and
the fourth limiting structure is configured to fit with the second limiting structure to limit movement of the connector in an axial direction,
wherein the charging device body is disposed inside the housing body, and the cable is electrically connected to the charging device body.
